(19) United States
(12) Patent Application Publication
(10) Pub. No.: US 2026/0068587 A1
(43) Pub. Date: Mar. 5, 2026

(54) SUBSTRATE TRANSFER UNIT, SUBSTRATE PROCESSING APPARATUS, AND TRANSFER DEVICE

(71) Applicant: EBARA CORPORATION, Tokyo (JP)

(72) Inventors: Takahiro ABE, Tokyo (JP); Mitsuru MIYAZAKI, Tokyo (JP); Akira IMAMURA, Tokyo (JP); Shozo TAKAHASHI, Tokyo (JP); Takuya INOUE, Tokyo (JP)

(21) Appl. No.: 19/315,880

(22) Filed: Sep. 2, 2025

(30) Foreign Application Priority Data
Sep. 4, 2024 (JP) 2024-152112

(51) Int. Cl. H01L 21/67; H01L 21/677; H01L 21/683; H01L 21/687

(52) U.S. Cl. CPC H01L 21/67196

(57) ABSTRACT

A substrate transfer unit includes a temporary placement stage and a transfer hand. Each of the temporary placement stage and the transfer hand holds a substrate at different locations depending on the processing state of the substrate.

### CROSS-REFERENCE TO RELATED APPLICATIONS

This application is based on and claims priority from Japanese Patent Application No. 2024-152112, filed on Sep. 4, 2024, with the Japan Patent Office, the disclosure of which is incorporated herein in its entirety by reference.

### TECHNICAL FIELD

The present disclosure relates to a substrate transfer unit, a substrate processing apparatus, and a transfer device.

### BACKGROUND

In the manufacture of semiconductor devices, various types of materials are repeatedly formed as films on a wafer to form a stacked structure. In order to form such a stacked structure, a technique for planarizing the surface of the wafer has become important. As a means of planarizing the wafer surface, a polishing device that performs the chemical mechanical polishing (CMP) is used.

A substrate processing apparatus includes a polishing module that performs the CMP, a cleaning module that cleans a wafer after polishing, and a drying module that dries the cleaned wafer. The wafer polished by the polishing module is transferred to the cleaning module and the drying module by a transfer robot, and is cleaned and dried by the cleaning module and the drying module. Hereinafter, the polishing module, cleaning module, and drying module may be collectively referred to simply as processing modules. See, for example, Japanese Patent Laid-Open Publication Nos. 2018-006549, 2010-050436, and 2019-042923.

### SUMMARY

In one embodiment, a substrate transfer unit includes a temporary placement stage on which a substrate is placed, and a transfer hand disposed within the same transfer space as the temporary placement stage to transfer the substrate placed on the temporary placement stage, and the temporary placement stage and the transfer hand are each configured to hold the substrate at different locations depending on a processing state of the substrate.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a diagram illustrating one embodiment of a substrate processing apparatus.

FIG. 2 is a diagram taken in the direction of arrow A in FIG. 1.

FIG. 3A is a diagram illustrating one embodiment of a substrate transfer unit.

FIG. 3B is a diagram illustrating another embodiment of the substrate transfer unit.

FIG. 4 is a diagram illustrating an example of a wafer processing process.

FIG. 5A is a diagram illustrating one embodiment of the substrate transfer unit.

FIG. 5B is a diagram illustrating one embodiment of a holding pin of a temporary placement stage.

FIG. 6 is a diagram illustrating a wafer before processing, which is transferred from a pen-cleaning chamber to the substrate transfer unit by a transfer robot of a second transfer chamber and is held by a first holding pin.

FIG. 7 is a diagram illustrating the wafer before processing, which is transferred from the pen-cleaning chamber to the substrate transfer unit by the transfer robot of the second transfer chamber and is held by the first holding pin.

FIG. 8 is a diagram illustrating a wafer clamped by a first clamp of a transfer hand through the close approach operation of two hand arms.

FIG. 9 is a diagram illustrating the wafer clamped by the first clamp of the transfer hand through the close approach operation of two hand arms.

FIG. 10 is a diagram illustrating the wafer clamped by a second clamp of the transfer hand.

FIG. 11 is a diagram illustrating the wafer clamped by the second clamp of the transfer hand.

FIG. 12 is a diagram illustrating the wafer held by a second holding pin of the temporary placement stage.

FIG. 13 is a diagram illustrating the wafer held by the second holding pin of the temporary placement stage.

FIG. 14 is a diagram illustrating one embodiment of a tube group for supplying a fluid to the transfer hand.

FIG. 15 is a diagram illustrating one embodiment of a fixing structure for fixing a distal end of the tube group.

FIG. 16 is a diagram illustrating one embodiment of the fixing structure for fixing the distal end of the tube group.

### DETAILED DESCRIPTION

In order to improve the productivity of wafers, it is desirable to optimize each process of a substrate processing apparatus (e.g., to improve wafer productivity without unnecessarily increasing the footprint size of the substrate processing apparatus). However, when a new processing module different from conventional processing modules is introduced into the substrate processing apparatus for various purposes, it may not be possible to insert the new processing module into the substrate processing apparatus as it is.

For example, when the new processing module has a different size from conventional processing modules, it is necessary to dispose the new processing module in a separate space. As a result, there is a concern that the new processing module may need to be spaced apart from existing processing modules (e.g., processing modules already inserted into the substrate processing apparatus).

In this case, a wafer processed by the existing processing modules may not be rapidly transferred to a new processing module, which may hinder the optimization of each process in the substrate processing apparatus. In particular, when the cleaning module and the drying module are spaced apart from each other, it is necessary to rapidly transfer the wafer between the cleaning module and the drying module without contaminating the wafer.

Furthermore, to implement the optimization of each process, there is a need for reliably transferring the wafer to the next process. For example, when a substrate transfer unit has a fragile structure or large size, it may be difficult to achieve the optimization of each process.

Therefore, the present disclosure provides a substrate transfer unit and a substrate processing apparatus capable of rapidly and reliably transferring a substrate (e.g., a wafer) between a plurality of processing modules without contaminating the substrate.

The need for reliably transferring a transfer target object to the next process is not necessarily limited to wafers, and the same exists for transfer target objects other than the wafers as well. Therefore, the present disclosure provides a transfer device capable of reliably transferring a transfer target object.

In one embodiment, a substrate transfer unit includes a temporary placement stage on which a substrate is placed, and a transfer hand disposed within the same transfer space as the temporary placement stage to transfer the substrate placed on the temporary placement stage, and each of the temporary placement stage and the transfer hand is configured to hold the substrate at different locations depending on a processing state of the substrate.

In one embodiment, the substrate transfer unit includes an extension/retraction mechanism that extends or retracts the transfer hand, and a lifting mechanism and a rotation mechanism that move the transfer hand in a vertical direction and a rotational direction, respectively.

In one embodiment, the lifting mechanism is configured to integrally move the temporary placement stage and the transfer hand in the vertical direction.

In one embodiment, the temporary placement stage includes a first holding pin that holds the substrate before processing, a second holding pin that holds the substrate after processing, and a holding pin switching mechanism that switches a holding pin for holding the substrate between the first holding pin and the second holding pin depending on the processing state of the substrate.

In one embodiment, the first holding pin and the second holding pin have different heights, and the temporary placement stage includes a pin cover that covers an upper surface of the second holding pin except when the second holding pin is holding the substrate.

In one embodiment, the transfer hand includes a first clamp that clamps the substrate before processing, and a second clamp that clamps the substrate after processing, the second clamp being positioned above the first clamp.

In one embodiment, the substrate transfer unit includes a hand lifting actuator that raises or lowers the transfer hand relative to the temporary placement stage, and the hand lifting actuator is configured to raise or lower the transfer hand during transfer of the substrate.

In one embodiment, the substrate transfer unit includes a stage lifting actuator that raises or lowers the temporary placement stage relative to the transfer hand, and the stage lifting actuator is configured to raise or lower the temporary placement stage during transfer of the substrate.

In one embodiment, a substrate processing apparatus includes the substrate transfer unit, a substrate processing unit that processes a substrate transferred by the substrate transfer unit, and a temporary placement stand that receives the substrate transferred by the substrate transfer unit.

In one embodiment, the substrate processing unit includes at least one of a drying module that dries the substrate and a measurement module that measures a surface condition of the substrate.

In one embodiment, the substrate processing apparatus includes a polishing section that polishes the substrate, and a cleaning section located between the polishing section and the substrate processing unit to clean the substrate polished by the polishing section.

In one embodiment, the substrate transfer unit includes a detection device that detects whether the substrate is present, and the substrate processing apparatus includes a control device that determines whether the substrate is present based on whether light emitted from the detection device is blocked by the substrate.

In one embodiment, a substrate processing apparatus includes a temporary placement stage that transfers a substrate in a first transfer direction and a second transfer direction orthogonal to the first transfer direction, and a transfer hand disposed within the same transfer space as the temporary placement stage to reciprocally transfer the substrate in the first transfer direction.

In one embodiment, a transfer device includes a transfer hand that transfers a target object, a tube group that supplies a fluid to the transfer hand, and a fixing structure that fixes a distal end of the tube group, and the tube group includes a first tube serving as a core line, and a second tube wound around the first tube so as to be in close contact with the first tube during movement of the transfer hand.

In one embodiment, the second tube is wound around the first tube multiple times in one direction.

In one embodiment, the fixing structure includes a movable end structure and a fixed end structure that fix the tube group, and the movable end structure is attached to the transfer hand.

Each of the temporary placement stage and the transfer hand is configured to hold the substrate at different locations depending on the processing state of the substrate. Accordingly, the substrate transfer unit may rapidly and reliably transfer the substrate to the next process without contaminating the substrate.

Hereinafter, embodiments of the present disclosure will be described with reference to the accompanying drawings. In addition, in the drawings described below, the same or equivalent components are denoted by the same reference numerals. and repeated descriptions are omitted. In the multiple embodiments described below, configurations not specifically described in one embodiment are the same as those in other embodiments, and repeated descriptions thereof are therefore omitted.

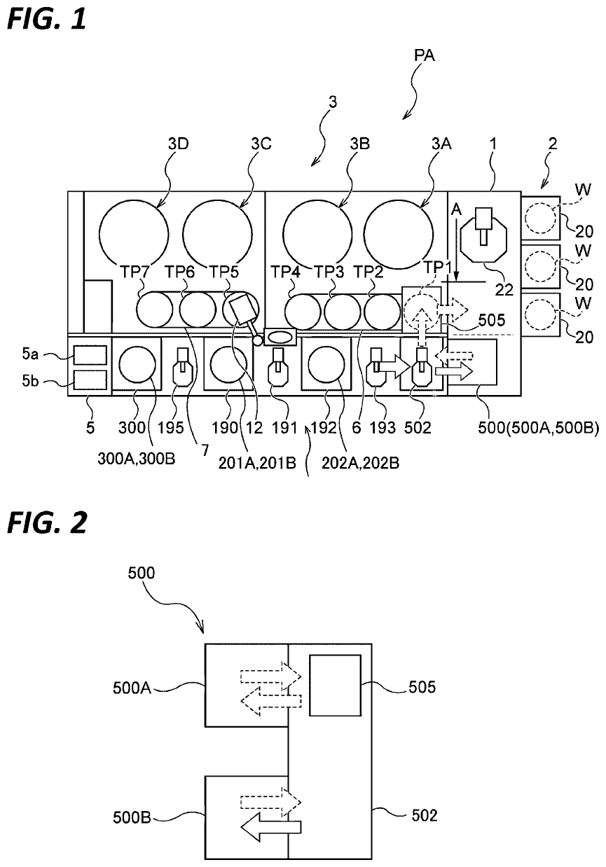

FIG. 1 is a diagram illustrating one embodiment of a substrate processing apparatus. As illustrated in FIG. 1, the substrate processing apparatus PA is an apparatus for processing a wafer W as an example of a substrate. The substrate processing apparatus PA includes a substantially rectangular housing 1.

The housing 1 divides the internal region of the substrate processing apparatus PA into a plurality of regions (e.g., a load/unload section 2, a polishing section 3, and a cleaning section 4) by a plurality of partition walls formed in the inside thereof. The load/unload section 2, polishing section 3, and cleaning section 4 are independently assembled and independently exhausted, respectively.

The substrate processing apparatus PA includes a control device 5 that controls the processing operations of the wafer W. The control device 5 is electrically connected to a plurality of devices arranged in the plurality of regions including the load/unload section 2, polishing section 3, and cleaning section 4, and is configured to control the operations of the respective devices.

The control device 5 includes a storage device 5a having a program stored therein, and a computational operation device 5b that executes computational operations in response to instructions included in the program. The control device 5 is configured with at least one computer. The storage device 5a includes a main storage device such as Random Access Memory (RAM) and an auxiliary storage device such as a Hard Disk Drive (HDD) or Solid State Drive (SSD). Examples of the computational operation device 5b include a Central Processing Unit (CPU) and a Graphics Processing Unit (GPU). However, a specific configuration of the control device 5 is not limited to these examples.

The load/unload section 2 includes two or more (three in the present embodiment) front load ports 20 on which wafer cassettes that store multiple wafers W are placed. The front load ports 20 are located adjacent to the housing 1 and are arranged along the width direction (the direction orthogonal to the longitudinal direction) of the substrate processing apparatus PA. The front load ports 20 are configured to enable the mounting of an open cassette, a Standard Manufacturing Interface (SMIF) pod, or a Front Opening Unified Pod (FOUP).

The substrate processing apparatus PA includes a transfer robot 22 disposed in the load/unload section 2, and a horizontal movement mechanism and a vertical movement mechanism for moving the transfer robot 22 horizontally and vertically. The horizontal and vertical movement mechanisms are not illustrated.

The transfer robot 22 is configured to move along the arrangement direction of the front load ports 20 (the width direction of the substrate processing apparatus PA) by the horizontal movement mechanism, and accesses to the wafer cassettes mounted on the front load ports 20.

The transfer robot 22 is configured to pick up a single wafer W to be polished from the wafer cassette and transfer the wafer W to a first linear transporter 6 (more specifically, first transfer position TP1). The first linear transporter 6 is a mechanism for transferring the wafer W between four transfer positions (first transfer position TP1, second transfer position TP2, third transfer position TP3, and fourth transfer position TP4 arranged along the longitudinal direction of the substrate processing apparatus PA).

The transfer robot 22 is accessible to a temporary placement stand 505 (described later) located above the first transfer position TP1 by the vertical movement mechanism. Accordingly, the transfer robot 22 is configured to pick up the wafer W placed on the temporary placement stand 505 and return it to the wafer cassette.

The polishing section 3 is a region where polishing (planarization) of the wafer W is performed. The polishing section 3 includes a first polishing module 3A, a second polishing module 3B, a third polishing module 3C, and a fourth polishing module 3D. The first polishing module 3A, second polishing module 3B, third polishing module 3C, and fourth polishing module 3D are arranged along the longitudinal direction of a polishing device, as illustrated in FIG. 1.

The first polishing module 3A, second polishing module 3B, third polishing module 3C, and fourth polishing module 3D all have substantially the same configuration. Thus, a configuration of the first polishing module 3A will be described below.

Although not illustrated, the first polishing module 3A includes a polishing table to which a polishing pad (polishing tool) having a polishing surface is attached, a top ring that holds the wafer W and presses it against the polishing pad on the polishing table, a polishing liquid supply nozzle for supplying a polishing liquid or dressing liquid (e.g., pure water) to the polishing pad, and a dresser for dressing the polishing surface of the polishing pad.

The substrate processing apparatus PA includes a second linear transporter 7 located adjacent to the third polishing module 3C and the fourth polishing module 3D. The second linear transporter 7 is a mechanism that transfers the wafer W between three transfer positions (fifth transfer position TP5, sixth transfer position TP6, and seventh transfer position TP7 arranged along the longitudinal direction of the substrate processing apparatus PA) in the direction in which the polishing modules 3C and 3D are arranged.

The first linear transporter 6 transfers the wafer W to the polishing modules 3A and 3B. The top ring of the first polishing module 3A moves between the polishing position and the second transfer position TP2 by a swing operation thereof.

Similarly, the top ring of the second polishing module 3B moves between the polishing position and the third transfer position TP3. The top ring of the third polishing module 3C moves between the polishing position and the sixth transfer position TP6. The top ring of the fourth polishing module 3D moves between the polishing position and the seventh transfer position TP7.

The substrate processing apparatus PA includes a swing transporter 12 located between the first linear transporter 6, the second linear transporter 7, and the cleaning section 4. The swing transporter 12 has a hand (not illustrated) capable of moving between the fourth transfer position TP4 and the fifth transfer position TP5. The swing transporter 12 is configured to transfer the wafer W from the first linear transporter 6 to the second linear transporter 7.

The wafer W polished in the polishing section 3 is transferred to the cleaning section 4. In the embodiment illustrated in FIG. 1, the cleaning section 4 is divided into a roll-cleaning chamber 190, a first transfer chamber 191, a pen-cleaning chamber 192, a second transfer chamber 193, a buff-processing chamber 300, a third transfer chamber 195, and a substrate transfer unit 502. A configuration of the substrate transfer unit 502 will be described later.

The substrate processing apparatus PA includes an upper roll-cleaning module 201A and a lower roll-cleaning module 201B disposed in the roll-cleaning chamber 190. The upper roll-cleaning module 201A and the lower roll-cleaning module 201B are arranged in the vertical direction. The upper roll-cleaning module 201A and the lower roll-cleaning module 201B have substantially the same configuration.

The upper roll-cleaning module 201A and the lower roll-cleaning module 201B are cleaning tools that clean the wafer W by pressing two rotating roll sponges (first cleaning tools) against the front and back surfaces of the wafer W, respectively, while supplying a cleaning liquid to the front and back surfaces of the rotating wafer W.

The substrate processing apparatus PA includes an upper pen-cleaning module 202A and a lower pen-cleaning module 202B disposed in the pen-cleaning chamber 192. The upper pen-cleaning module 202A and the lower pen-cleaning module 202B are arranged in the vertical direction. The upper pen-cleaning module 202A and the lower pen-cleaning module 202B have substantially the same configuration.

The upper pen-cleaning module 202A and the lower pen-cleaning module 202B are cleaning tools that clean the wafer W by pressing a rotating pencil sponge (second cleaning tool) against the surface of the wafer W while supplying a cleaning liquid to the surface of the rotating wafer W.

The substrate processing apparatus PA includes an upper buff-processing module 300A and a lower buff-processing module 300B disposed in the buff-processing chamber 300. The upper buff-processing module 300A and the lower buff-processing module 300B have substantially the same configuration. Thus, a configuration of the upper buff-processing module 300A will be described below.

Although not illustrated, the upper buff-processing module 300A includes a buff table on which the wafer W is installed, a buff head to which a buff pad (third cleaning tool) for performing buff-processing on the processing surface of the wafer W is attached, a buff arm for holding the buff head, and a conditioning element for performing conditioning (dressing) of the buff pad.

Hereinafter, the polishing module, cleaning module, and drying module may be collectively referred herein to simply as processing modules.

As described above, it is desirable to optimize each process of the substrate processing apparatus PA, but a new processing module introduced into the substrate processing apparatus PA may differ in size from conventional processing modules. In this case, the new processing module may need to be spaced apart from existing processing modules.

In the present embodiment, the substrate processing apparatus PA is configured to achieve the optimization of each process for the wafer W even under such circumstances. In particular, the substrate processing apparatus PA includes the substrate transfer unit 502 capable of rapidly and reliably transferring the wafer W between a plurality of processing modules without contaminating the wafer W.

FIG. 2 is a diagram taken in the direction of arrow A in FIG. 1. As illustrated in FIG. 2, the substrate processing apparatus includes the substrate transfer unit 502, a substrate processing unit 500 that processes the wafer W transferred by the substrate transfer unit 502, and the temporary placement stand 505 that receives the wafer W transferred by the substrate transfer unit 502.

In the embodiment illustrated in FIG. 2, the substrate processing unit 500 includes a measurement module 500A that measures the surface condition of the wafer W (e.g., the thickness of a film formed on the surface of the wafer W or the cleanliness of the surface of the wafer W), and a drying module 500B that dries the wafer W. In one embodiment, the substrate processing unit 500 may include at least one of the measurement module 500A and the drying module 500B.

The measurement module 500A is a stand-alone measurement device that measures the surface condition of the wafer W while the wafer W is stationary. Examples of the measurement device include a film thickness measuring device (e.g., In-line Thickness Monitor (ITM)) that measures the film thickness profile of the wafer W, or a measuring device (particle analyzer or particle counter) that measures the number of particles on the surface of the wafer W.

The control device 5 (see, e.g., FIG. 1) is electrically connected to the measurement module 500A. The control device 5 is configured to receive data measured by the measurement module 500A and control the operations of components of the substrate processing apparatus PA.

In the embodiment illustrated in FIG. 2, the measurement module 500A is located above the drying module 500B. The substrate transfer unit 502 is configured to be accessible to both the measurement module 500A and the drying module 500B.

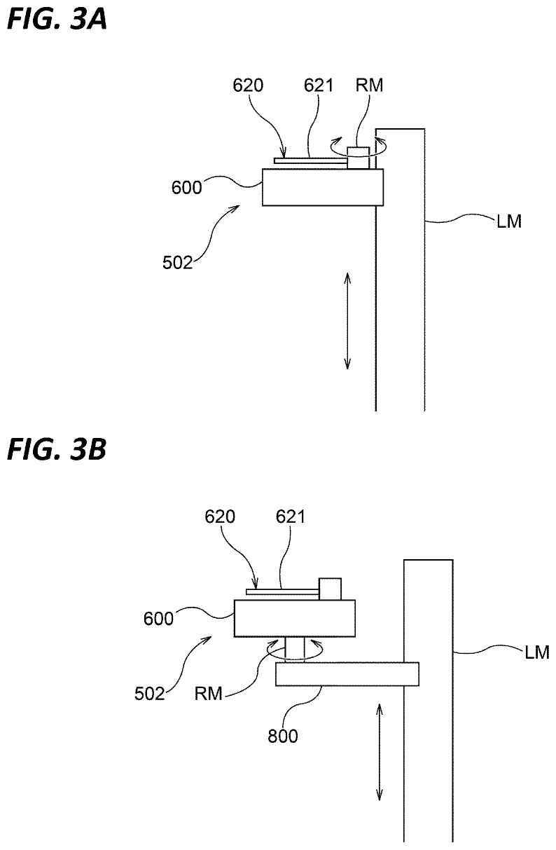

FIG. 3A is a diagram illustrating one embodiment of the substrate transfer unit. FIG. 3B is a diagram illustrating another embodiment of the substrate transfer unit. As illustrated in FIG. 3A, the substrate transfer unit 502 includes a temporary placement stage 600 on which the wafer W is placed, and a transfer hand 620 disposed within the same transfer space as the temporary placement stage 600 to transfer the wafer W placed on the temporary placement stage 600.

Furthermore, the substrate transfer unit 502 includes a lifting mechanism LM that integrally moves the temporary placement stage 600 and the transfer hand 620 in the vertical direction, and a rotation mechanism RM that moves at least the transfer hand 620 in the rotational direction.

The substrate transfer unit 502 is configured to move the wafer W in the vertical direction and the rotational direction through the operations of the lifting mechanism LM and the rotation mechanism RM. With this configuration, the substrate transfer unit 502 is accessible to the measurement module 500A and the drying module 500B by moving the transfer hand 620 in the vertical direction through the operation of the lifting mechanism LM. Furthermore, the substrate transfer unit 502 is accessible to the temporary placement stand 505 by changing the direction of the transfer hand 620 through the operation of the rotation mechanism RM.

As illustrated in FIG. 3B, the substrate transfer unit 502 further includes a carrier 800, on which the temporary placement stage 600, the transfer hand 620, and the rotation mechanism RM are placed, with the lifting mechanism LM connected thereto. With this configuration, the substrate transfer unit 502 moves not only the temporary placement stage 600 and the transfer hand 620 but also the rotation mechanism RM in the vertical direction through the operation of the lifting mechanism LM.

In the embodiment illustrated in FIG. 3B, the rotation mechanism RM is configured to rotate not only the transfer hand 620 but also the temporary placement stage 600. The rotation mechanism RM integrally rotates the transfer hand 620 and the temporary placement stage 600. Accordingly, the rotation mechanism RM may prevent contact between the temporary placement stage 600 and the transfer hand 620 due to the rotation of the transfer hand 620 relative to the temporary placement stage 600.

In the present embodiment, the cleaning section 4 is located between the polishing section 3 and the substrate processing unit 500 (see, e.g., FIG. 1). The substrate processing unit 500 is disposed in the load/unload section 2 and is located adjacent to the transfer robot 22.

As illustrated in FIG. 1, the substrate transfer unit 502 and the substrate processing unit 500 are arranged on a straight line along the longitudinal direction of the substrate processing apparatus PA. The temporary placement stand 505 is located above the first transfer position TP1. The substrate transfer unit 502 and the temporary placement stand 505 are arranged along the direction (the width direction of the substrate processing apparatus PA) orthogonal to the arrangement direction of the substrate transfer unit 502 and the substrate processing unit 500.

In one embodiment, the substrate processing unit 500, substrate transfer unit 502, and temporary placement stand 505 may be arranged along the width direction of the substrate processing apparatus PA. In this case, the substrate processing unit 500 is disposed outside the housing 1.

In the present embodiment, the longitudinal direction of the substrate processing apparatus PA is defined as a first transfer direction and the width direction of the substrate processing apparatus PA is defined as a second transfer direction. The temporary placement stage 600 is located to transfer the wafer W in both the first transfer direction and the second transfer direction. The transfer hand 620 is configured to reciprocally transfer the wafer W to and from the substrate processing unit 500 in the first transfer direction.

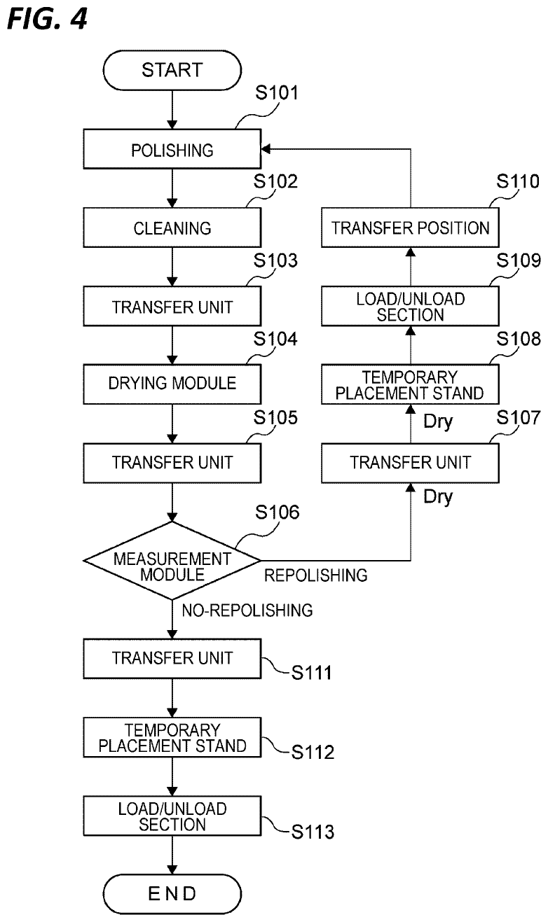

FIG. 4 is a diagram illustrating an example of a wafer processing process. As illustrated in steps S101 and S102 of FIG. 4, the wafer W is polished in the polishing section 3, and then, is cleaned in the cleaning section 4. Thereafter, the wafer W is transferred from the pen-cleaning chamber 192 to the substrate transfer unit 502 by a transfer robot (not illustrated) of the second transfer chamber 193.

As illustrated in step S103, the wafer W is transferred to the drying module 500B by the substrate transfer unit 502, and the drying module 500B dries the cleaned wafer W (see, e.g., step S104).

Thereafter, the substrate transfer unit 502 transfers the dried wafer W to the measurement module 500A (see, e.g., step S105), and the measurement module 500A measures the surface condition of the wafer W (see, e.g., step S106).

The control device 5 determines whether the wafer W needs to be re-polished based on the surface condition of the wafer W measured by the measurement module 500A. When re-polishing of the wafer W is required, the wafer W is transferred to the temporary placement stand 505 (see, e.g., steps S107 and S108). Thereafter, the transfer robot 22 transfers the wafer W placed on the temporary placement stand 505 from the load/unload section 2 to the first transfer position TP1 (see, e.g., steps S109 and S110).

When re-polishing of the wafer W is not required, the wafer W is transferred to the temporary placement stand 505 (see, e.g., steps S111 and S112), and the transfer robot 22 returns the wafer W placed on the temporary placement stand 505 from the load/unload section 2 to the front load port 20 (see, e.g., step S113).

In this way, the substrate transfer unit 502 transfers the wafer W before processing (e.g., after cleaning and before drying in the present embodiment) as well as the wafer W after processing (e.g., after drying in the present embodiment). To improve the productivity of the wafer W, it is necessary to rapidly transfer the wafer W without contaminating the wafer W. Therefore, the substrate transfer unit 502 is configured to rapidly transfer the wafer W without contaminating the wafer W. A configuration of the substrate transfer unit 502 will be described below with reference to the drawings.

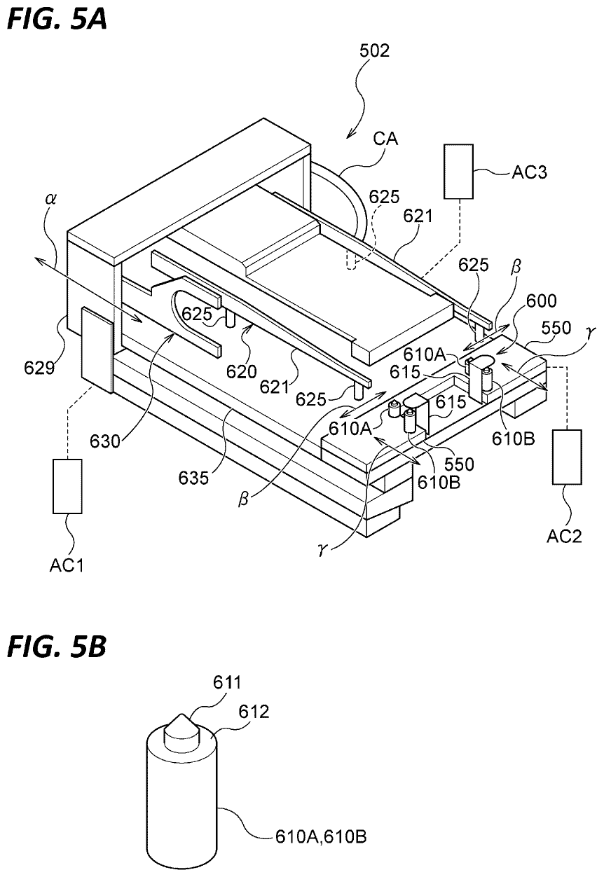

FIG. 5A is a diagram illustrating one embodiment of the substrate transfer unit. FIG. 5B is a diagram illustrating one embodiment of a holding pin of the temporary placement stage. In the embodiment illustrated in FIG. 5A, each of the temporary placement stage 600 and the transfer hand 620 is configured to hold the wafer W at different locations depending on the processing state of the wafer W (e.g., before processing or after processing). With this configuration, the substrate transfer unit 502 may transfer the wafer W without contaminating the wafer W.

Furthermore, each of the temporary placement stage 600 and the transfer hand 620 is configured to hold the wafer W before processing at one side location and to hold the wafer W after processing at the other side location. With this configuration, the substrate transfer unit 502 may rapidly and reliably transfer the wafer W.

As illustrated in FIG. 5A, the substrate transfer unit 502 includes a bracket 629 to which the transfer hand 620 is fixed, and an extension/retraction mechanism AC1 that extends or retracts (moves back and forth) the transfer hand 620 via the bracket 629.

The temporary placement stage 600 includes a carrying base 635 on which the bracket 629 is mounted. The extension/retraction mechanism AC1 is configured to move the bracket 629 along the horizontally extending carrying base 635. The extension/retraction mechanism AC1 is, for example, an air cylinder. The transfer hand 620 fixed to the bracket 629 moves horizontally together with the bracket 629 through the operation of the extension/retraction mechanism AC1 (see, e.g., arrow α in FIG. 5A).

The transfer hand 620 includes two parallel hand arms 621 and two protrusions 625 fixed respectively to the two hand arms 621. The protrusions 625 extend from the hand arms 621 toward the carrying base 635.

The two hand arms 621 are configured to be brought into close to or spaced apart from each other by an actuator AC3 such as an air cylinder (see, e.g., arrow β in FIG. 5A). When the two hand arms 621 are brought into close to each other, the protrusions 625 hold the peripheral edge of the wafer W.

The temporary placement stage 600 includes a plurality of first holding pins 610A for holding the wafer W before processing, a plurality of second holding pins 610B for holding the wafer W after processing, and a holding pin switching mechanism AC2 for switching holding pins for holding the substrate between the first holding pins 610A and the second holding pins 610B depending on the processing state of the wafer W.

The first and second holding pins 610A and 610B have different heights, but have substantially the same configuration. Thus, a configuration of the first holding pin 610A will be described below.

As illustrated in FIG. 5B, the first holding pin 610A has a conical upper surface 611 formed at the top thereof, and a shoulder 612 located at the lowermost portion of the upper surface 611. The shoulder 612 has a larger diameter than the upper surface 611 and is configured to hold the peripheral edge of the wafer W.

The temporary placement stage 600 includes a movable base 550 mounted on the carrying base 635. The holding pin switching mechanism AC2 is configured to move the movable base 550 along the direction in which the carrying base 635 extends (see, e.g., arrow γ in FIG. 5A).

The first and second holding pins 610A and 610B are fixed on the movable base 550, and move horizontally together with the movable base 550 through the operation of the holding pin switching mechanism AC2. The movement direction of the first and second holding pins 610A and 610B is the same as the movement direction of the transfer hand 620.

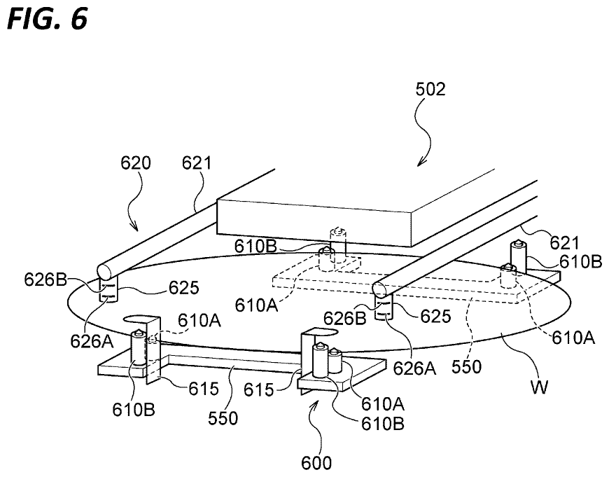

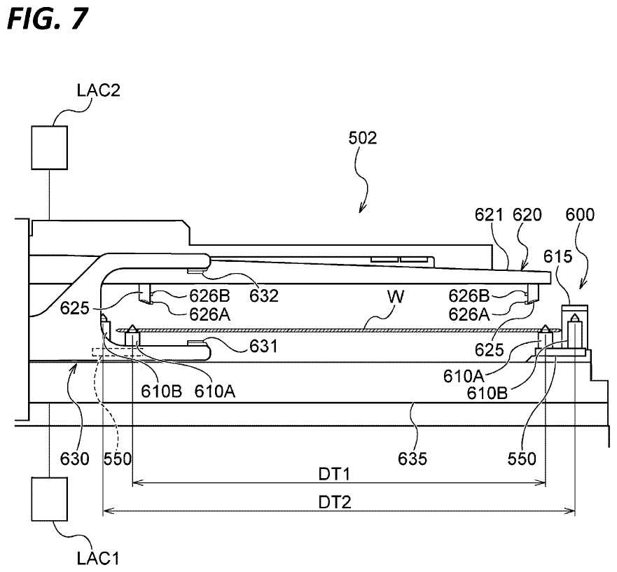

FIGS. 6 and 7 are diagrams illustrating the wafer before processing, which is transferred from the pen-cleaning chamber 192 to the substrate transfer unit 502 by a transfer robot (not illustrated) in the second transfer chamber 193 and is held by the first holding pins 610A. As illustrated in FIGS. 6 and 7, the wafer W transferred to the substrate transfer unit 502 is held by four first holding pins 610A (see, e.g., step S103 of FIG. 4).

The first and second holding pins 610A and 610B have different heights, and the upper surface 611 of each first holding pin 610A is located lower than the upper surface 611 of each second holding pin 610B. When lowering the wafer W from the transfer hand 620, the peripheral edge of the wafer W is guided by the conical upper surface 611 at the top of the holding pin 610A (or holding pin 610B), and is held by the shoulder 612 located at the lowermost portion of the upper surface 611.

The distance between the front and rear first holding pins 610A and 610A (distance DT1 in FIG. 7) is shorter than the distance between the front and rear second holding pins 610B and 610B (distance DT2 in FIG. 7) in the extension/retraction direction of the transfer hand 620 (e.g., the direction of arrow γ in FIG. 5A). Therefore, when the wafer W is held by all (four) first holding pins 610A, all (four) second holding pins 610B are not covered by the wafer W.

As illustrated in FIG. 7, the substrate transfer unit 502 includes a stage lifting actuator LAC1 that raises or lowers the temporary placement stage 600 (more specifically, the carrying base 635 and the movable base 550) vertically relative to the transfer hand 620.

The stage lifting actuator LAC1 is configured to raise or lower the temporary placement stage 600 during the transfer of the wafer W. The stage lifting actuator LAC1 is, for example, an air cylinder. The control device 5 is electrically connected to the stage lifting actuator LAC1, and raises or lowers the temporary placement stage 600 by operating the stage lifting actuator LAC1.

The stage lifting actuator LAC1 lowers the temporary placement stage 600, for example, to avoid collision between the pin cover 615 and the transfer hand 620 (more specifically, the protrusion 625) during the movement of the transfer hand 620.

The stage lifting actuator LAC1 raises the temporary placement stage 600 to place the wafer W on the temporary placement stage 600 when the transfer hand 620 moves to a position above the temporary placement stage 600 while holding the wafer W.

The substrate transfer unit 502 includes a hand lifting actuator LAC2 that raises or lowers the transfer hand 620 vertically relative to the temporary placement stage 600. The hand lifting actuator LAC2 is configured to raise or lower the transfer hand 620 during the transfer of the wafer W.

The hand lifting actuator LAC2 is, for example, an air cylinder. The control device 5 is electrically connected to the hand lifting actuator LAC1, and raises or lowers the transfer hand 620 by operating the hand lifting actuator LAC2.

When the transfer hand 620 receives the wafer W from the first holding pin 610A, a processing (rotary drying) stage (not illustrated) of the drying module 500B, or a measurement stage (not illustrated) of the measurement module 500A, the hand lifting actuator LAC2 lowers the transfer hand 620 to the holding height of the wafer W. Thereafter, the hand lifting actuator LAC2 raises the transfer hand 620 to the transfer height of the wafer W while clamping the peripheral edge of the wafer W by the transfer hand 620.

When the transfer hand 620 transfers the wafer W to the second holding pin 610B, the processing stage of the drying module 500B, the measurement stage of the measurement module 500A, or the stage of the temporary placement stand 505, the hand lifting actuator LAC2 lowers the transfer hand 620 to the holding height of the wafer W. Thereafter, the transfer hand 620 releases the peripheral edge of the wafer W, and the hand lifting actuator LAC2 raises the transfer hand 620 to a predetermined standby height.

The wafer W before processing is, in other words, the wafer W that has been cleaned but not yet dried. Therefore, the wafer W before processing is in a wet state. By positioning the upper surface of each first holding pin 610A below the upper surface of each second holding pin 610B, liquid droplets or particles adhering to the surface of the wafer W will not adhere to the second holding pin 610B even when the first holding pin 610A holds the wafer W in a wet state. Therefore, the temporary placement stage 600 may prevent contamination of the second holding pin 610B.

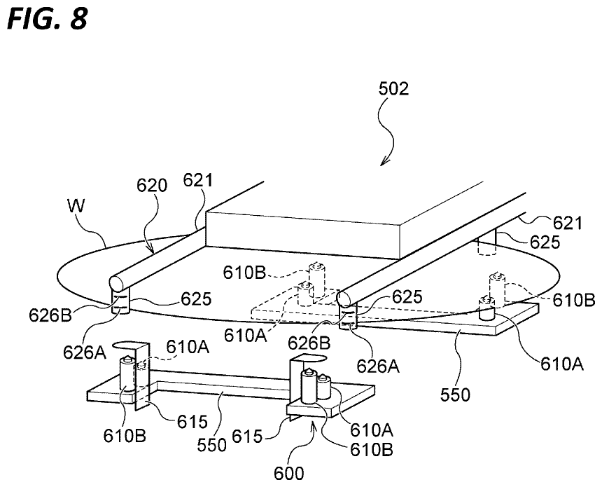

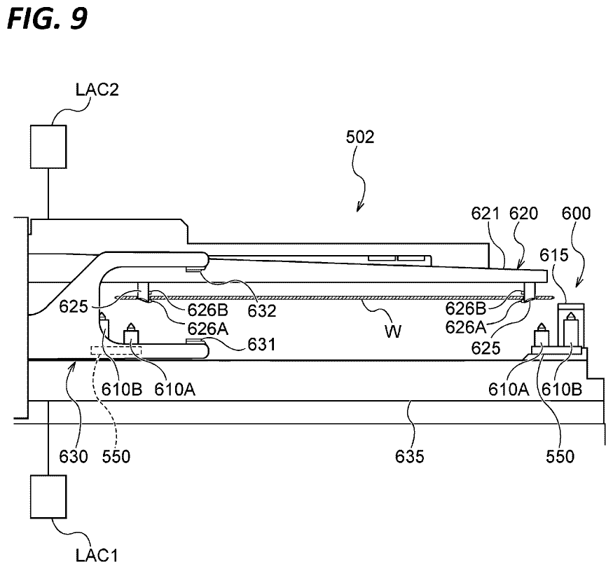

FIGS. 8 and 9 are diagrams illustrating the wafer clamped by a first clamp of the transfer hand 620 through the close approach operation of two hand arms 621. The transfer hand 620 includes a first clamp 626A and a second clamp 626B, which are formed on the protrusion 625. Both the first clamp 626A and the second clamp 626B have a hook shape and are configured to grip the peripheral edge of the wafer W.

The first clamp 626A is configured to clamp the wafer W before processing. The second clamp 626B is configured to clamp the wafer W after processing. The second clamp 626B is located above the first clamp 626A. Therefore, even when the first clamp 626A holds the wafer W in a wet state, liquid droplets or particles adhering to the surface of the wafer W do not adhere to the second clamp 626B. Therefore, the transfer hand 620 may prevent contamination of the second clamp 626B.

While holding the wafer W before processing with the first clamp 626A, the transfer hand 620 pivots 90 degrees toward the direction in which the drying module 500B is located by the rotation mechanism RM, and then advances by the expansion/retraction mechanism AC1 to transfer the wafer W to the drying module 500B (see, e.g., step S104 of FIG. 4). At this time, the wafer W in a wet state passes above the second holding pin 610B adjacent to the drying module 500B. Therefore, there is a risk that liquid droplets or particles adhering to the surface of the wafer W may fall.

Therefore, the temporary placement stage 600 includes a pin cover 615 that covers the upper surface of the second holding pin 610B except when the wafer W is held by the second holding pin 610B. The pin cover 615 is attached to the carrying base 635, but not to the movable base 550. Therefore, even when the movable base 550 moves, the pin cover 615 does not move together with the movable base 550.

The pin cover 615 prevents liquid droplets or particles adhering to the surface of the wafer W from adhering to the second holding pin 610B. With this configuration, the temporary placement stage 600 may prevent contamination of the second holding pin 610B even when the wet wafer W passes above the second holding pin 610B.

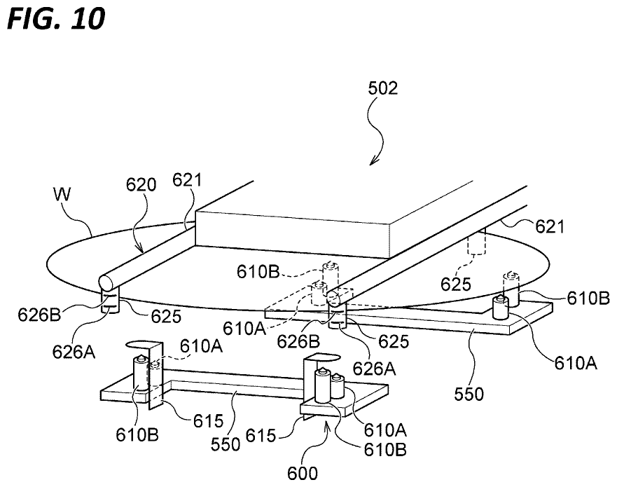

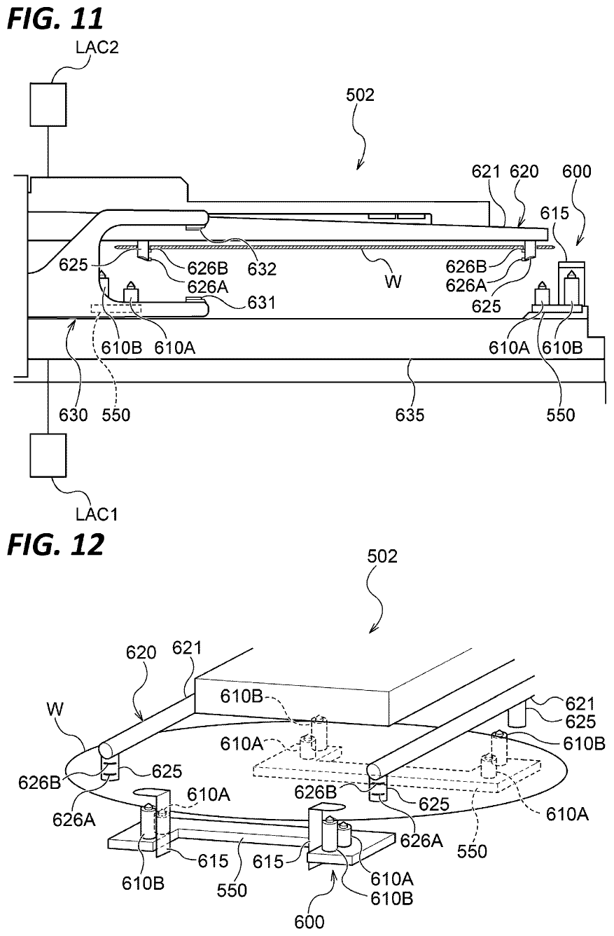

FIGS. 10 and 11 are diagrams illustrating the wafer clamped by the second clamp of the transfer hand. After the wafer W is dried in the drying module 500B, the wafer W is again held by the transfer hand 620, is retracted by the extension/retraction mechanism AC1, and is pivoted 90 degrees toward the direction in which the substrate transfer unit 502 is located by the rotation mechanism RM, and is transferred to the substrate transfer unit 502 (see, e.g., step S105 of FIG. 4).

As illustrated in FIGS. 10 and 11, the transfer hand 620 clamps the dried wafer W by the second clamp 626B. The second clamp 626B is located above the first clamp 626A and is maintained in a clean state. Therefore, even when the second clamp 626B clamps the wafer W after processing, the transfer hand 620 may place the wafer W on the temporary placement stage 600 without contaminating the wafer W.

When the transfer hand 620 holds the wafer W before processing with the first clamp 626A, the hand lifting actuator LAC2 lowers the transfer hand 620 by a first distance so that the height of the wafer W matches the height of the first clamp 626A (first lowering operation). In contrast, when the transfer hand 620 holds the wafer W before processing with the second clamp 626A, the hand lifting actuator LAC2 lowers the transfer hand 620 by a second distance, which is greater than the first distance, so that the height of the wafer W matches the height of the second clamp 626B (second lowering operation).

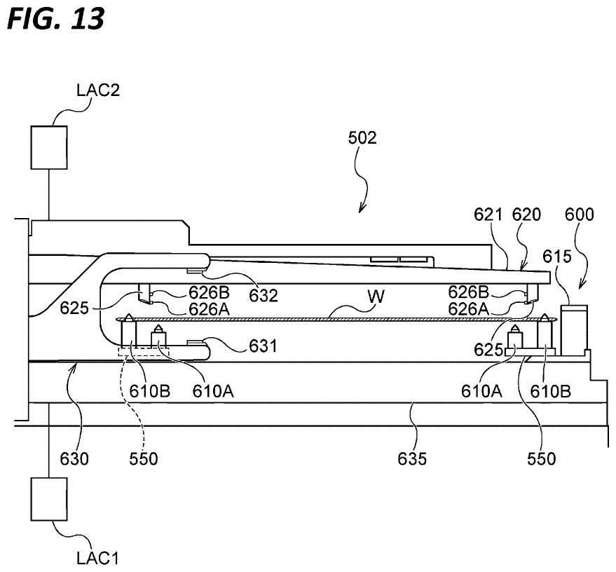

FIGS. 12 and 13 are diagrams illustrating the wafer held by the second holding pin of the temporary placement stage. When the transfer hand 620 places the wafer W on the temporary placement stage 600, the four second holding pins 610B arranged around the wafer W move closer to each other and hold the wafer W through the operation of the front and rear movable bases 550 along the extension/retraction direction of the transfer hand 620. At this time, at least a portion of the second holding pin 610B is exposed from the pin cover 615.

The second holding pin 610B has a higher height than the first holding pin 610A and is maintained in a clean state. Therefore, the second holding pin 610B may hold the wafer W after processing without contaminating the wafer W.

The substrate transfer unit 502 includes a detection device 630 that detects whether the wafer W is present for transfer (see, e.g., FIGS. 5A, 7, 9, 11 and 13). In the present embodiment, the detection device 630 is an optical sensor having a light-emitting element 631 and a light-receiving element 632. The light-emitting element 631 is configured to vertically emit light toward the wafer W transferred to the substrate transfer unit 502. The light-receiving element 632 is positioned opposite the light-emitting element 631 to receive the light emitted from the light-emitting element 631. In the present embodiment, the light-receiving element 632 is located above the light-emitting element 631.

The control device 5 is electrically connected to the detection device 630 and is configured to determine whether the wafer W is present based on whether the light emitted from the light-emitting element 631 is blocked by the wafer W. When the light-receiving element 632 receives the light emitted from the light-emitting element 631, the light-receiving element 632 sends a detection signal to the control device 5.

When the control device 5 receives the detection signal from the light-receiving element 632, the control device 5 determines that no wafer W is present in the substrate transfer unit 502. In contrast, when the light emitted from the light-emitting element 631 is blocked by the wafer W, the light-receiving element 632 does not detect the light emitted from the light-emitting element 631, and the light-receiving element 632 does not send a detection signal to the control device 5. In this way, the control device 5 determines whether the wafer W is present in the substrate transfer unit 502 based on whether the detection signal is sent.

When the wafer W before processing, transferred to the substrate transfer unit 502, is placed on the temporary placement stage 600, the light emitted from the light-emitting element 631 is blocked by the wafer W, and the control device 5 determines that the wafer W is present on the temporary placement stage 600 (see, e.g., FIG. 7).

Thereafter, when the transfer hand 620 clamps the wafer W and transfers it to the drying module 500B, the light emitted from the light-emitting element 631 is not blocked by the wafer W, and the control device 5 determines that the wafer W has been transferred from the substrate transfer unit 502.

When the transfer hand 620 introduces the wafer W dried in the drying module 500B into the substrate transfer unit 502 and moves it to a position above the temporary placement stage 600, the light emitted from the light-emitting element 631 is blocked by the wafer W, and the control device 5 determines that the wafer W has been transferred to the substrate transfer unit 502 (see, e.g., FIG. 11).

Thereafter, the control device 5 determines that the wafer W is present in the substrate transfer unit 502 during a period after the transfer hand 620 places the wafer W on the temporary placement stage 600 and until the wafer W is transferred from the temporary placement stage 600 to the temporary placement stand 505.

Once the wafer W has been transferred to the temporary placement stand 505, the light emitted from the light-emitting element 631 is no longer blocked by the wafer W, and the control device 5 determines that the wafer W has been transferred from the substrate transfer unit 502.

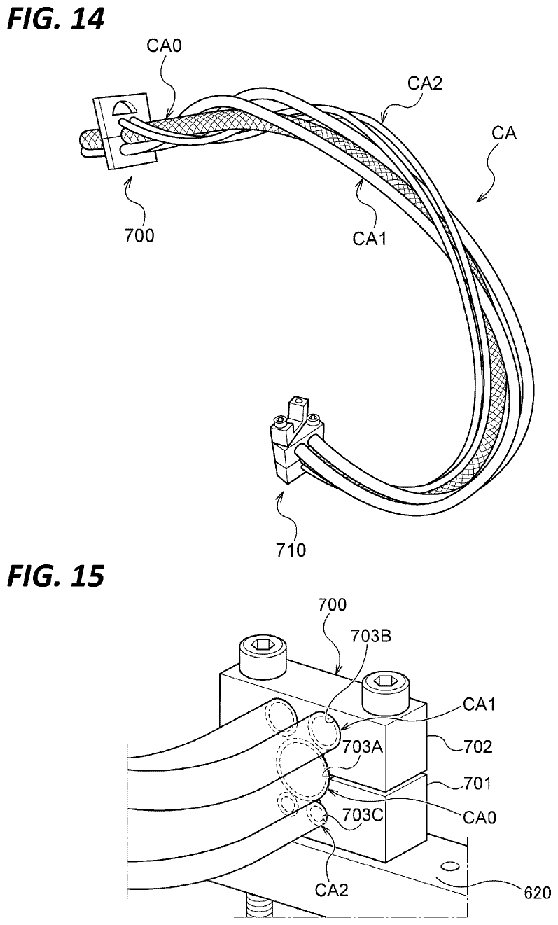

FIG. 14 is a diagram illustrating one embodiment of a tube group for supplying a fluid to the transfer hand. In order to optimize each process of the substrate processing apparatus PA, it is necessary to reliably transfer the wafer W, which is a transfer target object, to the next process. To implement such transfer, it is desirable for the substrate transfer unit 502 to have a highly durable configuration.

In particular, the substrate transfer unit 502 includes a tube group CA for supplying a fluid required for the operation thereof (see, e.g., FIG. 5A). The tube group CA connects a movable device such as the transfer hand 620 with a stationary device such as a fluid supply source (not illustrated). Therefore, repeated extension/retraction operations of the transfer hand 620 may cause the tube group CA to come into contact with the wall surface of the substrate transfer unit 502 or the transfer hand 620, potentially resulting in damage.

Although it is considered to accommodate the tube group CA in a cable bear (registered trademark) (not illustrated) to prevent such damage to the tube group CA, using a cable bear may generate dust that could contaminate the wafer W, and there are also concerns regarding chemical resistance. Furthermore, the cable bear requires a large installation space, which increases the overall size of the substrate transfer unit 502 and, consequently, the overall size of the substrate processing apparatus PA.

Therefore, in the embodiment illustrated in FIG. 14, the tube group CA is configured to prevent the generation of dust and eliminate the need for a large installation space. More specifically, the tube group CA includes a first tube CA0 serving as a core line, and second tubes CA1 and CA2 wound around the first tube CA0 so as to be in close contact with the first tube CA0 during the movement of the transfer hand 620.

As illustrated in FIG. 14, the first tube CA0 is composed of a single tube, while each of the second tubes CA1 and CA2 is composed of two tubes. The second tubes CA1 and CA2 have different diameters. In this specification, for ease of viewing the drawings, no individual reference numerals are given to each of the plurality of second tubes CA1 and CA2. Instead, simplified reference numerals are given to each of the second tubes CA1 and CA2.

The first tube CA0 is thicker and more durable than the second tubes CA1 and CA2. The second tubes CA1 and CA2 are wound around the first tube CA0 in one direction. In one embodiment, the second tubes CA1 and CA2 may be wound around the first tube CA0 multiple times.

By this winding, the second tubes CA1 and CA2 are in close contact with the first tube CA0, and even when the transfer hand 620 moves, the second tubes CA1 and CA2 do not come loose from the first tube CA0, but rather remain in a wound state around the first tube CA0 while moving together with the transfer hand 620.

The second tubes CA1 and CA2 are wound around the first tube CA0 without using a fastener such as a binding band. Therefore, they may flexibly bend along with the movement of the transfer hand 620. As a result, the second tubes CA1 and CA2 are not bent or pulled excessively.

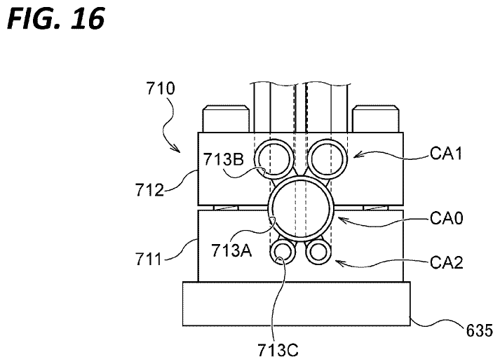

FIGS. 15 and 16 are diagrams illustrating one embodiment of a fixing structure for fixing the distal end of the tube group. As illustrated in FIGS. 15 and 16, the substrate transfer unit 502 includes a fixing structure for fixing the distal end of the tube group CA.

The fixing structure includes a movable-end structure 700 (see, e.g., FIG. 15) and a fixed-end structure 710 (see, e.g., FIG. 16) for clamping the tube group CA. As illustrated in FIG. 15, the movable-end structure 700 is attached to the transfer hand 620. The movable-end structure 700 has a lower end 701 for fixing the second tube CA2 and an upper end 702 for fixing the second tube CA1.

The second tube CA2 is inserted into an insertion hole 703C of the lower end 701, and the second tube CA1 is inserted into an insertion hole 703B of the upper end 702. The first tube CA0 is inserted into an insertion hole 703A formed by the lower end 701 and the upper end 702. The lower end 701 and the upper end 702 are close to each other, clamping the tube group CA.

As illustrated in FIG. 16, the fixed-end structure 710 is attached to the carrying base 635. The fixed-end structure 710 has a lower end 711 for fixing the second tube CA2 and an upper end 712 for fixing the second tube CA1.

The second tube CA2 is inserted into an insertion hole 713C of the lower end 711, and the second tube CA1 is inserted into an insertion hole 713B of the upper end 712. The first tube CA0 is inserted into an insertion hole 713A formed by the lower end 711 and the upper end 712. The lower end 711 and the upper end 712 are close to each other, clamping the tube group CA.

By fixing the tube group CA using the fixed structure (e.g., the movable-end structure 700 and the fixed-end structure 710), it is possible to prevent the second tubes CA1 and CA2 wound around the first tube CA0 from coming loose.

The necessity of reliably transferring a transfer target object to the next process is not necessarily limited to the wafer W. Such a necessity exists likewise for a transfer target object other than the wafer W. Therefore, the substrate transfer unit 502 configured to reliably transfer the wafer W to the next process has been described in the above-described embodiment, but the configuration applied to the substrate transfer unit 502 may also be applied to a transfer device capable of reliably transferring a transfer target object other than the wafer W.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate transfer unit comprising:
a temporary placement stage on which a substrate is placed, and
a transfer hand disposed within a same transfer space as the temporary placement stage and configured to transfer the substrate placed on the temporary placement stage,
wherein the temporary placement stage and the transfer hand are each configured to hold the substrate at different locations depending on a processing state of the substrate.

2. The substrate transfer unit according to claim 1, further comprising:
an extension/retraction actuator configured to extend or retract the transfer hand;
a lift configured to move the transfer hand in a vertical direction; and
a rotator configured to move the transfer hand in a rotational direction.

3. The substrate transfer unit according to claim 2, wherein the lift is configured to integrally move the temporary placement stage and the transfer hand in the vertical direction.

4. The substrate transfer unit according to claim 1, wherein the temporary placement stage includes:
a first holding pin that holds the substrate before processing,
a second holding pin that holds the substrate after processing, and
a holding pin switching actuator that switches a holding pin for holding the substrate between the first holding pin and the second holding pin depending on the processing state of the substrate.

5. The substrate transfer unit according to claim 4, wherein the first holding pin and the second holding pin have different heights, and
the temporary placement stage includes a pin cover that covers an upper surface of the second holding pin except when the second holding pin is holding the substrate.

6. The substrate transfer unit according to claim 1, wherein the transfer hand includes:
a first clamp that clamps the substrate before processing, and
a second clamp that clamps the substrate after processing, the second clamp being positioned above the first clamp.

7. The substrate transfer unit according to claim 1, further comprising:
a hand lifting actuator that raises or lowers the transfer hand relative to the temporary placement stage,
wherein the hand lifting actuator is configured to raise or lower the transfer hand during transfer of the substrate.

8. The substrate transfer unit according to claim 1, further comprising:
a stage lifting actuator that raises or lowers the temporary placement stage relative to the transfer hand,
wherein the stage lifting actuator is configured to raise or lower the temporary placement stage during transfer of the substrate.

9. A substrate processing apparatus comprising:
the substrate transfer unit according to claim 1;
a substrate processing unit that processes a substrate transferred by the substrate transfer unit, and
a temporary placement stand that receives the substrate transferred by the substrate transfer unit.

10. The substrate processing apparatus according to claim 9, wherein the substrate processing unit includes at least one of a drying module that dries the substrate and a measurement module that measures a surface condition of the substrate.

11. The substrate processing apparatus according to claim 10, further comprising:
a polishing section that polishes the substrate, and
a cleaning section located between the polishing section and the substrate processing unit to clean the substrate polished by the polishing section.

12. The substrate processing apparatus according to claim 9, wherein the substrate transfer unit includes a detector that detects whether the substrate is present, and
the substrate processing apparatus includes a controller that determines whether the substrate is present based on whether light emitted from the detector is blocked by the substrate.

13. A substrate processing apparatus comprising:
a temporary placement stage configured to transfer a substrate in a first transfer direction and a second transfer direction orthogonal to the first transfer direction, and
a transfer hand disposed within a same transfer space as the temporary placement stage and configured to reciprocally transfer the substrate in the first transfer direction.

14. A transfer device comprising:
a transfer hand configured to transfer a target object;
a tube group configured to supply a fluid to the transfer hand; and
a fixing structure configured to fix a distal end of the tube group, wherein the tube group includes
a first tube serving as a core line, and
a second tube wound around the first tube so as to be in close contact with the first tube during movement of the transfer hand.

15. The transfer device according to claim 14, wherein the second tube is wound around the first tube multiple times in one direction.

16. The transfer device according to claim 14, wherein the fixing structure includes a movable end structure and a fixed end structure that fix the tube group, and
the movable end structure is attached to the transfer hand.
